(19) United States
(12) Patent Application Publication
(10) Pub. No.: US 2009/0152589 A1
(43) Pub. Date: Jun. 18, 2009

(54) Systems And Methods To Increase Uniaxial Compressive Stress In Tri-Gate Transistors

(76) Inventors: Titash Rakshit, Hillsboro, OR (US); Martin D. Giles, Portland, OR (US); Tahir Ghani, Portland, OR (US); Anand Murthy, Portland, OR (US); Stephen M. Cea, Hillsboro, OR (US)

Correspondence Address: INTEL CORPORATION;c/o CPA Global, P.O. BOX 52050, MINNEAPOLIS, MN, 55402, US

(21) Appl. No.: 11/958,275

(22) Filed: Dec. 17, 2007

(51) Int. Cl. H01L 29/778; H01L 21/8234

(52) U.S. Cl. 257/190; 438/279; 257/E21.616; 257/E29.246

(57) ABSTRACT

A transistor structure that increases uniaxial compressive stress on the channel region of a tri-gate transistor comprises at least two semiconductor bodies formed on a substrate, each semiconductor body having a pair of laterally opposite sidewalls and a top surface, a common source region formed on one end of the semiconductor bodies, wherein the common source region is coupled to all of the at least two semiconductor bodies, a common drain region formed on another end of the semiconductor bodies, wherein the common drain region is coupled to all of the at least two semiconductor bodies, and a common gate electrode formed over the at least two semiconductor bodies, wherein the common gate electrode provides a gate electrode for each of the at least two semiconductor bodies and wherein the common gate electrode has a pair of laterally opposite sidewalls that are substantially perpendicular to the sidewalls of the semiconductor bodies.

### BACKGROUND

In the manufacture of integrated circuit devices, multi-gate transistors are often used to provide enhanced transistor functionality. As is known in the art, the presence of multiple gates, such as three gates in a tri-gate transistor, allows the channel region of the transistor to become fully depleted while in operation. This enables the multi-gate transistor to be more efficient and switch faster.

It is well known in the art that the channel region of a transistor may be stressed or strained to further improve device performance. Conventional techniques for producing stress or strain on the channel region of a transistor are well known as applied to planar transistors. When such techniques are applied to multi-gate transistors, however, several design challenges are present. For instance, when a stress-inducing layer is deposited in the source and drain regions of a multi-gate transistor, such as epitaxially deposited silicon germanium, the three-dimensional nature of the multi-gate transistor allows free surfaces to exist on the silicon germanium. The silicon germanium will expand and relax along these free surfaces. This results in a substantial decrease in the amount of stress that the silicon germanium layer exerts on the channel region of the multi-gate transistor.

As such, improved techniques are needed to fully utilize the stress exerting potential of a silicon germanium layer on the channel region of a multi-gate transistor.

### BRIEF DESCRIPTION OF THE DRAWINGS

FIG. 1 illustrates a conventional tri-gate transistor.

FIGS. 2A and 2B illustrate a tri-gate transistor array.

FIG. 3 is a method of forming a tri-gate transistor array with one uninterrupted source region and one uninterrupted drain region.

FIGS. 4A and 4B illustrate a tri-gate transistor array having connected source regions and connected drain regions.

FIGS. 5A and 5B illustrate a tri-gate transistor array having one uninterrupted source region and one uninterrupted drain region.

### DETAILED DESCRIPTION

Described herein are systems and methods of increasing stress in the channel region of multi-gate transistors. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide an array of tri-gate, PMOS transistors where the individual source and drain regions of adjacent transistors are merged into continuous and uninterrupted source and drain regions. As will be explained in more detail below, connecting the adjacent source and drain regions increases the uniaxial compressive strain that is exerted on the channel regions of the tri-gate transistors. Those of skill in the art will recognize that increasing this strain enhances hole mobility in the channel regions, thereby improving drive current.

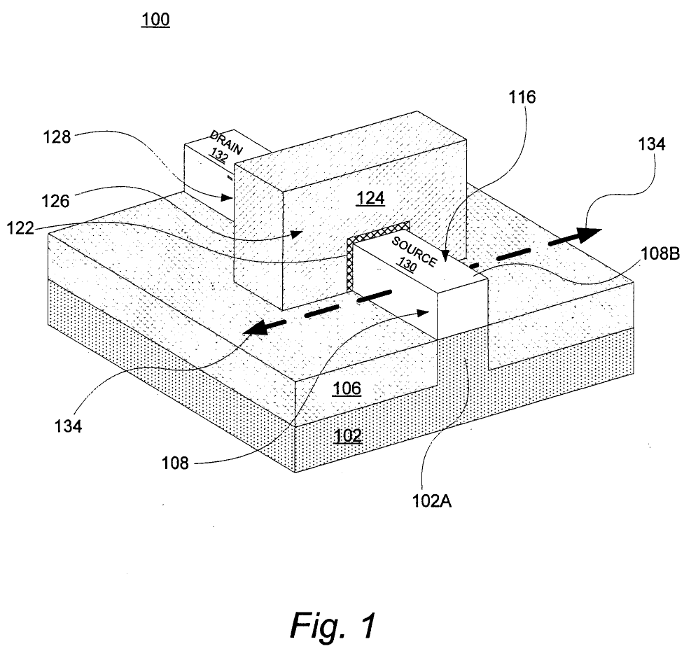

FIG. 1 is a perspective view of a conventional multi-gate transistor 100, such as a PMOS transistor, having a strained semiconductor body in accordance with an implementation of the invention. The multi-gate transistor 100, here a tri-gate transistor 100, is formed on a substrate 102. The substrate 102 is generally a semiconductor substrate, such as a monocrystalline silicon substrate or a gallium arsenide substrate, although in some implementations a silicon-on-insulator substrate may be used. An insulating layer 106, such as a silicon dioxide layer, is formed on the substrate 102. In some implementations, the tri-gate transistor 100 may be formed on any well-known insulating substrate such as substrates formed from silicon dioxide, nitrides, oxides, and sapphires.

The tri-gate transistor 100 includes a semiconductor body 108 formed on the substrate 102. The semiconductor body 108 has a pair of laterally opposite sidewalls separated by a distance which defines a semiconductor body width. Additionally, the semiconductor body 108 has a top surface 116. The distance between the top surface 116 and the insulating layer 106 defines a body height. In an implementation of the invention, the body height is substantially equal to the body width. In an implementation of the invention, the body 108 has a width and height that is less than 30 nanometers (nm) and ideally less than 20 nm.

In some implementations, the semiconductor body 108 may be a dual-material structure having at least one portion formed of the same material as the substrate 102, such as silicon, and an epitaxially deposited layer used to induce a strain in the semiconductor body 108, such as silicon germanium (Si₁₋ₓGeₓ). As such, in some implementations, the semiconductor body 108 may have a silicon core and a silicon germanium shell. It should be noted that a portion of the semiconductor body, which will be used to form a channel region as described below, will consist only of silicon and will not include the silicon germanium shell.

In most implementations of the invention, however, the semiconductor body 108 may be formed using epitaxially grown silicon germanium. For instance, conventional methods may be used to initially form a silicon fin 102A on the substrate 102. The insulating layer 106 may then be deposited around this silicon fin 102A at a height that is less than the height of the silicon fin 102A. Next, as shown in FIG. 1, a portion of the silicon fin 102A that will be used to form source and drain regions may be etched back until it is the same height as the insulating layer 106. Silicon germanium may then be epitaxially grown atop the etched back silicon fin 102A to form the semiconductor body 108. A portion of the silicon fin 102A that is not etched back may be used to form a channel region, as described below, which will consist only of silicon and will not include silicon germanium. More specifically, when the silicon fin 102A is etched back, a portion of the silicon fin 102A may be protected by a gate electrode 124 and therefore not subjected to the etching process. This protected portion of the silicon fin 102A forms the channel region for the transistor 100.

A source region 130 and a drain region 132 are formed in the semiconductor body 108 on opposite sides of the gate electrode 124. The source and drain regions 130/132 are formed of the same conductivity type. The source and drain regions 130/132 may have a uniform doping concentration or may include sub-regions of different concentrations or doping profiles such as tip regions (e.g., source/drain extensions). In some implementations the source and drain regions 130/132 may have the same doping concentration and profile while in other implementations they vary.

The channel region is sandwiched between the source region 130 and the drain region 132 and is surrounded by the gate electrode 124. The channel region is generally formed of doped or undoped silicon. In an implementation of the invention, when the channel region is doped, it is typically doped to the opposite conductivity type of the source and drain regions 130/132. If doped, the channel region may be uniformly doped or may include “halo” regions. Because the channel region is surrounded on three sides by the gate electrode 124, the transistor 100 can be operated in a fully depleted manner.

The tri-gate transistor 100 further includes a gate dielectric layer 122 that is formed on and adjacent to three sides of the channel region, namely the sidewalls and the top surface of the channel region. The gate dielectric layer 122 is under the gate electrode 124 and may be formed using any well-known gate dielectric material, including but not limited to silicon dioxide (SiO₂), silicon oxynitride (SiOₓN_{y}), silicon nitride (Si₃N₄), and high-k dielectric materials such as hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In an implementation of the invention, the gate dielectric layer 122 may be formed to an thickness of between 5 and 200 Angstroms (Å).

The gate electrode 124 is formed on and adjacent to the gate dielectric layer 122 as shown in FIG. 1. The gate electrode 124 has a pair of laterally opposite sidewalls 126 and 128 separated by a distance which defines the gate length (Lg) of transistor 100. In an implementation of the invention, the laterally opposite sidewalls 126 and 128 of the gate electrode 124 run in a direction perpendicular to the laterally opposite sidewalls 110 and 112 of the semiconductor body 108.

The gate electrode 124 can be formed of any suitable gate electrode material. In an implementation of the invention, the gate electrode 124 may be formed from materials that include, but are not limited to, polysilicon, tungsten, ruthenium, palladium, platinum, cobalt, nickel, hafnium, zirconium, titanium, tantalum, aluminum, titanium carbide, zirconium carbide, tantalum carbide, hafnium carbide, aluminum carbide, other metal carbides, metal nitrides, and metal oxides. In some implementations, the gate electrode 124 may be a composite stack of thin films, such as but not limited to a polysilicon/metal electrode or a metal/polysilicon electrode.

Although not shown in FIG. 1, a pair of spacers may be formed on the laterally opposite sidewalls 126 and 128 of the gate electrode 124. The spacers may be formed of a material that is typically used to form spacers in integrated circuit applications, such as silicon nitride.

In alternate implementations of the invention, although FIG. 1 shows a silicon germanium layer that has been deposited over a silicon fin, the semiconductor body 108 may be formed using a silicon body having a small portion etched away and replaced with silicon germanium. In further implementations, the semiconductor body 108 may be formed using a silicon body having a significant portion etched away and replaced with silicon germanium. For example, deep cavities or recesses may be etched into the semiconductor body 108 and filled with silicon germanium to form the source and drain regions. In further implementations, the material used to induce strain may be formed from alternate semiconductor materials known in the art.

In the transistor 100, the epitaxially grown silicon germanium layers that form at least a portion of the source and drain regions 130/132 exert a uniaxial compressive stress on the channel region, thereby enhancing hole mobility in the channel region and improving the drive current. Unfortunately, the full compressive stress exertion potential of the silicon germanium layer is never realized due to free surfaces that exist in the width direction of the semiconductor body 108. Along these free surfaces, the silicon germanium layers tend to relax and expand in the horizontal direction as indicated by the heavy arrows 134. This substantially reduces the amount of compressive stress that is exerted on the channel region of the transistor 100.

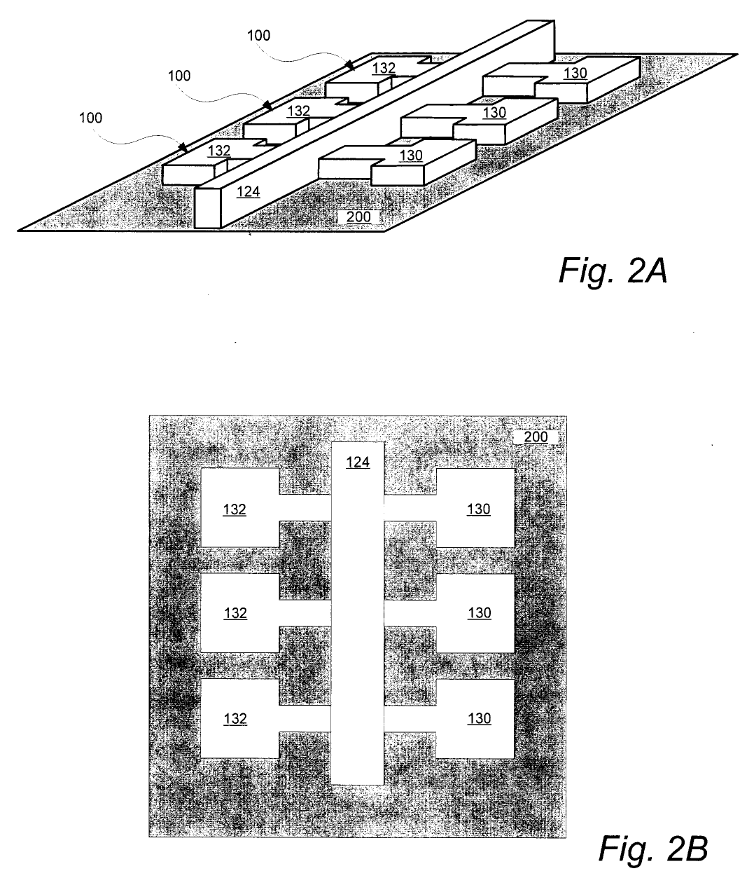

FIGS. 2A and 2B illustrate an array of tri-gate transistors 100 on a surface of a semiconductor substrate 200. FIG. 2A is a perspective view and FIG. 2B is a top-down view. The tri-gate transistors 100 share a common gate electrode 124. For clarity, certain features such as the gate dielectric layer 122 and the spacers are not shown. In some implementations, the tri-gate transistors 100 in FIG. 2 may be patterned such that they have wider source and drain regions 130/132 relative to the rest of the semiconductor body. The wider structure aids in landing contacts on the source and drain regions 130/132. Here, as with the transistor 100 shown in FIG. 1, any silicon germanium layers will tend to relax and expand in the horizontal direction due to the presence of free surfaces, thereby reducing the amount of compressive stress that is exerted on the channel regions of the array of transistors 100.

Therefore, in accordance with an implementation of the invention, to minimize horizontal expansion and therefore increase compressive stress in the channel regions of the array of transistors, the source and drain regions 130/132 of adjacent transistors are formed in a connected configuration. This provides one uninterrupted source region and one uninterrupted drain region for the array of tri-gate transistors. By connecting adjacent source and drain regions 130/132, the silicon germanium is blocked from expanding in the horizontal direction. This forces the silicon germanium to redirect its stress into the channel regions of transistors.

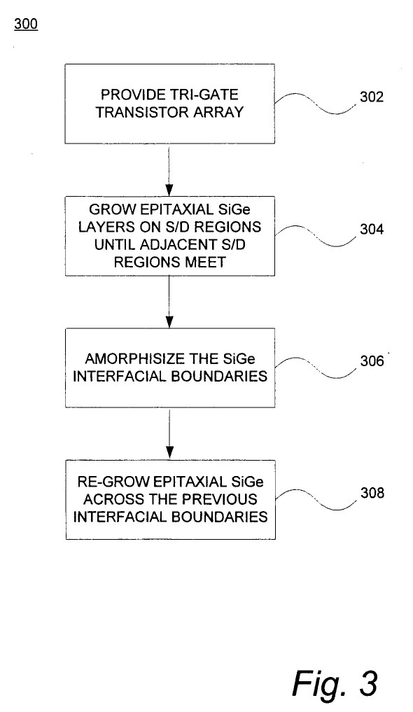

FIG. 3 is a process 300 to connect the source/drain regions of adjacent tri-gate transistors using epitaxial overgrowth. FIGS. 2A/B, 4A/B, and 5A/B illustrate structures formed when the process 300 of FIG. 3 is carried out.

Turning to FIG. 3, the process 300 begins by forming a multi-gate transistor array on a substrate, such as a tri-gate transistor array formed on a semiconductor substrate (process 302 of FIG. 3). Those of skill in the art will recognize that there are a variety of well known fabrication processes for generating an array of tri-gate transistors. Any such process may be used here to form the array of transistors. Again, FIGS. 2A/B illustrate an array of conventionally formed tri-gate transistors 100.

Next, in one implementation of the invention, epitaxial layers of silicon germanium are grown on at least the source and drain regions of the transistors 100 of the array to increase their thicknesses until silicon germanium layers on adjacent source/drain regions come into contact with one another (304). More specifically, the silicon germanium layers on adjacent source regions 130 are grown until they come into contact with one another to form a continuous or uninterrupted source region. The continuous source region therefore provides a common source region for all of the semiconductor bodies. Likewise, the silicon germanium layers on adjacent drain regions 132 are grown until they come into contact with one another to form a continuous or uninterrupted drain region. Again, this continuous drain region provides a common drain region for all of the semiconductor bodies. This connected structure prevents the source and drain silicon germanium regions from relaxing or expanding in the horizontal direction and increases the overall volume of silicon germanium. Both of these aspects increase the uniaxial compressive stress that can be transferred to the channel region of the transistors.

In some implementations, silicon germanium is used to form the source and drain regions 130/132 in their entirety, as described above with reference to FIG. 1. In such an implementation, the epitaxial deposition process may then continue until the silicon germanium layers come into contact with one another, thereby connecting adjacent transistors 100. In other implementations, if the outermost layers of the source and drain regions 130/132 are formed of a material other than silicon germanium, such as silicon, then silicon germanium layers may be epitaxially deposited over the source and drain regions 130/132 and grown until they come into contact with one or more adjacent transistors 100. In further implementations, alternate stress-exerting semiconductor materials other than silicon germanium may be used if they provide a similar form of stress on the channel regions of the transistors. In implementations of the invention, the epitaxial deposition process may be carried out at a temperature that falls between 700° C. and 900° C. for a time duration that falls between 2 minutes and 15 minutes.

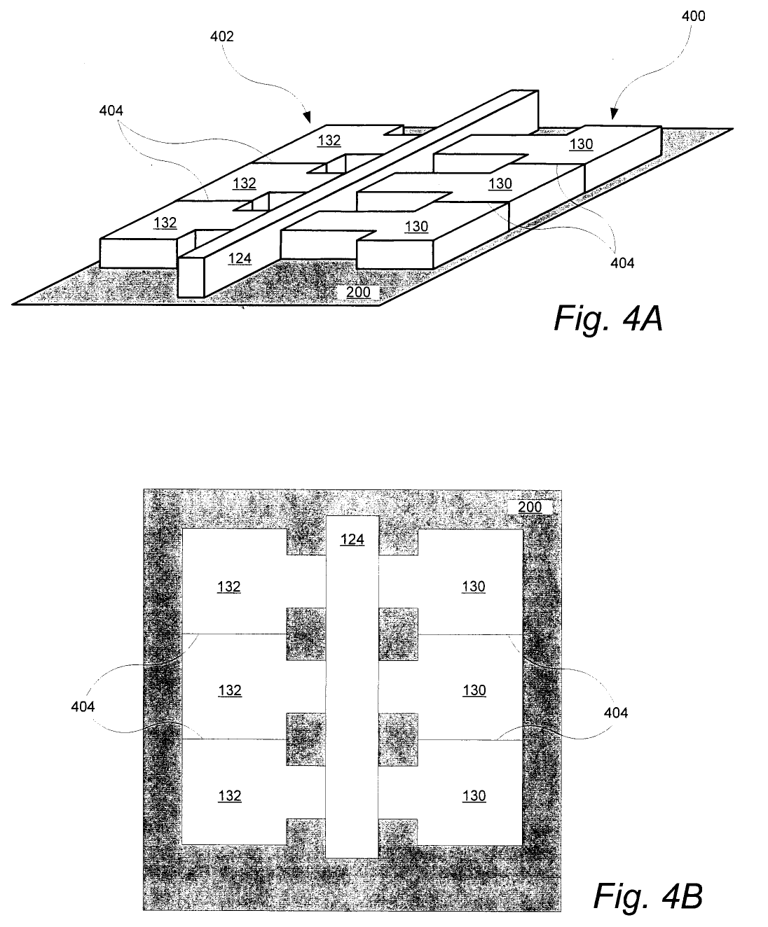

FIGS. 4A and 4B illustrate the array of transistors 100 when the silicon germanium layers have been epitaxially grown until adjacent source regions 130 make contact to form an uninterrupted source region 400 and adjacent drain regions 132 make contact to form an uninterrupted drain region 402. FIG. 4A provides a perspective view while FIG. 4B provides a top-down view. As shown, there are no longer gaps between adjacent source regions 130 or adjacent drain regions 132.

Interfacial boundaries 404 are formed when the growing source and drain regions come into contact with each other. These interfacial boundaries 404 may have dislocations and other flaws that can negatively affect the impact of the uninterrupted source and drain regions 400/402 on the silicon germanium layers. It is advantageous to therefore reduce or eliminate these interfacial boundaries.

In an implementation of the invention, these interfacial boundaries may be reduced or eliminated using a two-part process. First, an amorphization process may be carried out to amorphize the silicon germanium along the interfacial boundaries (306). In an implementation of the invention, the amorphization process may be carried out using an ion implantation process that amorphizes the silicon germanium layers wherever they come into contact. In one implementation, the ion implantation process may be carried out at an energy that falls between 2 kilo-electron volts (keV) and 20 keV and at an ion dosage that falls between 1×10¹⁴ atoms/cm³ and 1×10¹⁶ atoms/cm³. Ion species that are conventionally used for amorphization purposes in the semiconductor art may be used here.

Next, a solid phase, low temperature epitaxial regrowth process may be used to regrow or recrystallize the silicon germanium across the interfacial boundaries (308). The epitaxial regrowth allows the silicon germanium layer to be have a continuous crystalline structure across the previous interfacial boundaries with a minimal amount of dislocations.

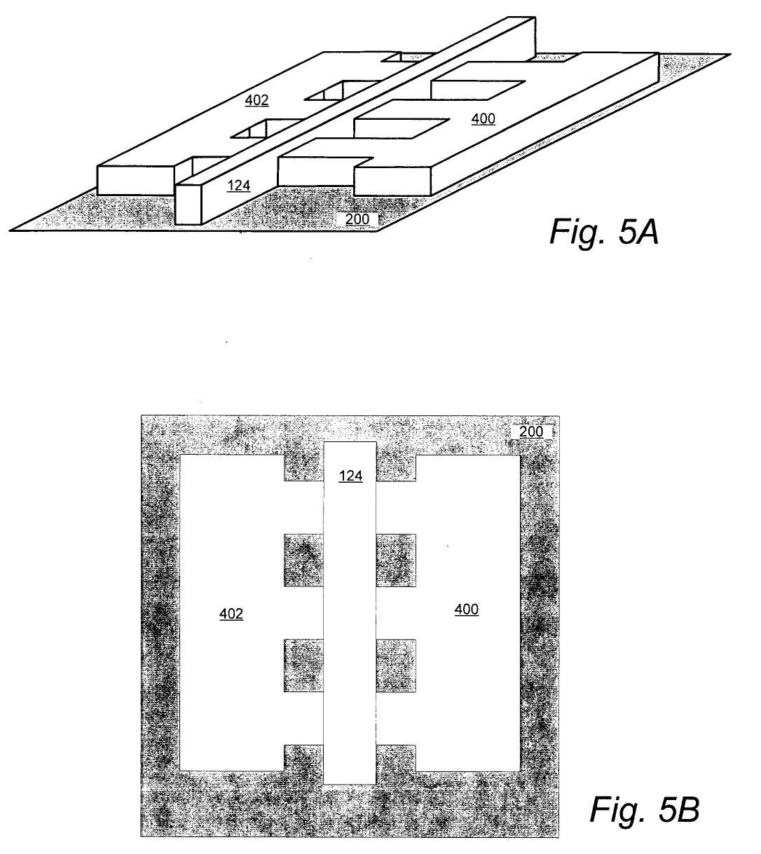

FIGS. 5A and 5B illustrate the array of tri-gate transistors 100 after the interfacial boundaries are eliminated. As shown, a common source region 400 is formed that is a single, continuous source region with no interfacial boundaries. The common source region 400 substantially consists of homogenous crystalline silicon germanium. Likewise, a common drain region 402 is formed that is also a single, continuous drain region with no interfacial boundaries. The common drain region substantially consists of homogenous crystalline silicon germanium.

In an alternate implementation of the invention, the uninterrupted source and drain regions 400/402 may be formed using a method other than epitaxial overgrowth. In some implementations, the array of transistors may be initially formed with connected source and drain regions. For instance, the semiconductor bodies used in a tri-gate transistor array are generally formed using a photolithographic etching process. In accordance with implementations of the invention, the optical mask used to define the semiconductor bodies may be drawn such that the middle portion of the semiconductor bodies are isolated but the source and drain pads are connected.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
at least two semiconductor bodies formed on a substrate, each semiconductor body having a pair of laterally opposite sidewalls and a top surface;
a common source region formed on one end of the semiconductor bodies, wherein the common source region is coupled to all of the at least two semiconductor bodies;
a common drain region formed on another end of the semiconductor bodies, wherein the common drain region is coupled to all of the at least two semiconductor bodies; and
a common gate electrode formed over the at least two semiconductor bodies, wherein the common gate electrode provides a gate electrode for each of the at least two semiconductor bodies and wherein the common gate electrode has a pair of laterally opposite sidewalls that are substantially perpendicular to the sidewalls of the semiconductor bodies.

2. The apparatus of claim 1, wherein the continuous source region comprises silicon germanium.

3. The apparatus of claim 1, wherein the continuous drain region comprises silicon germanium.

4. The apparatus of claim 1, further comprising:
gate dielectric layers formed between the common gate electrode and each of the at least two semiconductor bodies; and
a pair of spacers formed on the laterally opposite sidewalls of the gate electrode.

5. The apparatus of claim 1, wherein the semiconductor bodies comprise silicon, the common source region comprises silicon germanium, and the common drain region comprises silicon germanium.

6. A method comprising:
providing an array of discrete semiconductor bodies on a substrate, wherein each semiconductor body includes a first end and a second end;
growing a first set of silicon germanium layers on the first ends of the semiconductor bodies of the array until the silicon germanium layers of the first set contact one another along interfacial boundaries; and
growing a second set of silicon germanium layers on the second ends of the semiconductor bodies of the array until the silicon germanium layers of the second set contact one another along interfacial boundaries.

7. The method of claim 6, further comprising:
using an ion implantation process to amorphize the silicon germanium layers along the interfacial boundaries; and
re-growing crystalline silicon germanium along the interfacial boundaries.

8. The method of claim 6, wherein the first ends comprise source regions and wherein each source region has a width that is larger than the width of their respective semiconductor body.

9. The method of claim 6, wherein the second ends comprise drain regions and wherein each drain region has a width that is larger than the width of their respective semiconductor body.

10. The method of claim 6, wherein the growing of the first and second sets of silicon germanium layers comprises epitaxially growing the first and second set of silicon germanium layers.

11. A method comprising:
forming an array of semiconductor bodies on a substrate, each semiconductor body having a top surface, a pair of laterally opposite sidewalls, a first end, and a second end;
forming a gate electrode across the array of semiconductor bodies, the gate electrode having a pair of laterally opposite sidewalls that are substantially perpendicular to the sidewalls of the semiconductor bodies;
etching away portions of the semiconductor bodies not covered by the gate electrode;
epitaxially depositing silicon germanium on the etched portions of the semiconductor bodies, wherein the deposition continues until the silicon germanium on each semiconductor body comes into contact with silicon germanium on at least one adjacent semiconductor body along an interfacial boundary.

12. The method of claim 11, further comprising:
amorphizing the silicon germanium along the interfacial boundaries; and
recrystallizing the silicon germanium along the previous interfacial boundaries.

13. The method of claim 11, wherein a gate dielectric layer is deposited on the semiconductor bodies prior to the forming of the gate electrode.

14. The method of claim 11, wherein the amorphizing of the silicon germanium comprises using an ion implantation process to amorphize the silicon germanium.

15. The method of claim 14, wherein the ion implantation process is carried out at an energy between 2 keV and 20 keV and at an ion dosage between 1×10¹⁴ atoms/cm³ and 1×10¹⁶ atoms/cm³.

16. The method of claim 11, further comprising forming a pair of spacers for each semiconductor body on the laterally opposite sidewalls of the gate electrode.

17. A method comprising:
forming an array of semiconductor bodies on a substrate, each semiconductor body having a top surface and a pair of laterally opposite sidewalls;
forming a gate electrode across the array of semiconductor bodies, the gate electrode having a pair of laterally opposite sidewalls that are substantially perpendicular to the sidewalls of the semiconductor bodies;
etching a pair of recesses in each semiconductor body on opposite sides of the gate electrode;
epitaxially depositing silicon germanium within the pair of recesses of each semiconductor body to form source and drain regions; and
continuing to epitaxially deposit the silicon germanium until the silicon germanium on each semiconductor body comes into contact with the silicon germanium on at least one adjacent semiconductor body along an interfacial boundary.

18. The method of claim 17, further comprising:
implanting ions along the interfacial boundaries to amorphize at least a portion of the silicon germanium; and
re-growing the silicon germanium wherever it has been amorphized.

19. The method of claim 17, further comprising:
forming a gate dielectric layer on each semiconductor body prior to the formation of the gate electrode; and
forming a pair of spacers on each semiconductor body on the laterally opposite sidewalls of the gate electrode.

20. A method comprising:
depositing a layer of silicon germanium on a substrate;
patterning the silicon germanium layer using a photolithography process to form a common source region and a common drain region connected by an array of semiconductor bodies;
forming a gate dielectric layer on each semiconductor body of the array; and
forming a gate electrode across the array of semiconductor bodies atop the gate dielectric layers.

21. The method of claim 20, wherein each of the semiconductor bodies of the array comprises a top surface, a pair of laterally opposite sidewalls, a first end, and a second end.

22. The method of claim 21, wherein the common source region comprises a continuous source region that is coupled to all of the semiconductor bodies at their first ends.

23. The method of claim 22, wherein the common drain region comprises a continuous drain region that is coupled to all of the semiconductor bodies at their second ends.

24. The method of claim 21, wherein the gate electrode comprises a pair of laterally opposite sidewalls that are substantially perpendicular to the laterally opposite sidewalls of the semiconductor bodies of the array.
